(19) United States
(12) Patent Application Publication
(10) Pub. No.: US 2006/0154400 A1
(43) Pub. Date: Jul. 13, 2006

(54) Method of forming a nanogap and method of manufacturing a nano field effect transitor for molecular device and bio-sensor, and molecular device and bio-sensor manufactured using the same

(76) Inventors: Yang-Kyu Choi, Yuseong-gu (KR); Ju-Hyun Kim, Yuseong-gu (KR)

Correspondence Address: Klaus P. Stoffel;Wolff & Samson PC, One Boland Drive, West Orange, NJ, 07052, US

(21) Appl. No.: 11/328,789

(22) Filed: Jan. 10, 2006

(30) Foreign Application Priority Data
Jan. 10, 2005 (KR) 10-2005-0002294

(51) Int. Cl. H01L 21/00; G03C 5/00

(52) U.S. Cl. 438/49; 430/321; 438/5

(57) ABSTRACT

The present invention relates to a method of forming a nanogap, a method of manufacturing a nano field effect transistor for a molecular device or a bio-sensor, and a fabrication thereof, and more particularly, to a method of forming a high reproductive nanogap using a thin layer with a molecular size or a size which is similar to that of a molecule and a nano field effect transistor manufactured by the method of forming the nanogap. The method of forming a nanogap according to the present invention comprises steps of (a) forming sequentially an insulating layer, a first metal layer and a hard mask on a silicon substrate; (b) etching partially the first metal layer using the mask as an etching mask; (c) forming a self-assembled monolayer (SAM) on a side surface of the first metal layer to form a nanogap on the silicon substrate; (d) depositing metal on the entire structure including the mask to form a second metal layer; (e) removing the metal deposited on the hard mask using a lift-off process by etching the mask formed in step (a) and (f) etching the SAM formed in step (c) to form the nanogap.

This Nonprovisional application claims priority under 35 U.S.C. § 119(a) on Patent Application No. 10-2005-0002294 filed in Korea on Jan. 10, 2005, the entire contents of which are hereby incorporated by reference.

### BACKGROUND OF THE INVENTION

1. Field of the Invention

The present invention relates to a method of forming a nanogap, a manufacturing method and a structure of a nano field effect transistor (nanoFET) for a molecular device or a bio-sensor, and more particularly, to a method of forming a highly reproducable nanogap using a film as thin as a molecular size or as a size similar to the molecular size, and to a nano field effect transistor manufactured by the method of forming the nanogap.

2. Description of the Background Art

A metal nanogap in which metal plates are located both sides of a nanometer sized gap is valuable in manufacturing a molecular device and a bio-sensor.

With continuous technological developments, a high integration of semiconductor device has been achieved along with performance enhancement and scaledown.

Due to the technological limitations (light source wavelengths, light dispersions, lens numerical aperture (N/A), and absence of photoresist) of the lithography method used in a semiconductor manufacturing process, scaledown of the device now gets to the limit.

To overcome such limitations to such miniaturization of the semiconductor devices, a molecular device has been proposed.

The molecular device is a new conceptual device in which molecules are used as channels.

To implement such a molecular device, a gap corresponding to a molecular length should be formed between two metal plates which function as the source/drain electrodes of the conventional field effect transistor, respectively.

As noted above, however, a method of forming a gap of molecular length using the conventional lithography process has reached a technical limit.

The bio-sensor is a detector which detects specific molecules constituting organisms such as enzyme or antibodies.

There are chemical, optical and electrical methods for detecting a specific molecule. The electrical detecting method is the most accurate among such methods because this method can rapidly detect a small quantity of a specific molecule.

The electrical detecting method also has advantages in that it is possible to manufacture a portable sensor at a low manufacturing cost by mass production of the small-sized highly-integrated sensors using the conventional silicon processing technology.

Since it is possible to detect a specific substance by changing electrical characteristics at both ends of the nanogap structure after filling it with a solution containing a biological material, the nanogap structure with a width of several nanometers can be used as an electrical sensor.

As the gap of the nanogap structure becomes narrower, its sensitivity to detect becomes greater, so that to detection becomes more efficient.

However, forming the gap of a size smaller than several nanometers by means of the lithography process used for the conventional silicon processing has the technical limitations such as the wavelength of the light source to be used, the dispersion phenomenon of light and the like. Moreover, since the formation of a nanogap using the lithography method requires a complicated process and its reproducibility become lower as the desired gap size becomes smaller, the formation of the several nanometers sized gap required for the high performance bio-sensor is difficult to form.

To produce the molecular device or the bio-sensor, new method to form the nanogap of a size of several nanometers must be used.

### SUMMARY OF THE INVENTION

An object of the present invention for solving the above mentioned problems is to provide a method of forming a nanogap with the size of several nanometers, comprising steps of forming, on a silicon substrate, two metal layers and a self-assembled monolayer (SAM) or an aluminum oxide (Al₂O₃) layer through the atomic layer deposition process, and then etching (or etching partially) the SAM or the Al₂O₃ layer.

Another object of the present invention is to provide a method of manufacturing a highly integrated high-performance bio-sensor and a nano field effect transistor, which is a molecular device substituting for the conventional device, through the above method of forming the nanogap.

A method of forming a planar nanogap for a bio-sensor according to one embodiment of the present invention comprises steps of (a) forming sequentially an insulating layer, a first metal layer and a hard mask on a silicon substrate; (b) etching partially the first metal layer using the mask as an etching mask; (c) forming a self-assembled monolayer (SAM) on a side surface of the first metal layer to form a nanogap on the silicon substrate; (d) depositing metal on the entire structure including the mask to form a second metal layer; (e) removing the metal deposited on the hard mask using lift-off process by etching the mask formed in step (a) and (f) etching the SAM formed in step (c) to form the nanogap.

It is desirable that the first and second metal layers are formed using aurum (Au).

It is desirable that the first and second metal layers are formed by any one of the vapor deposition process, the sputtering process or the pulsed laser deposition (PLD) process.

A method of forming a vertical nanogap for the bio-sensor according to one embodiment of the present invention comprises steps of a) forming sequentially an insulating layer and a first metal layer on a silicon substrate; b) forming sequentially a self-assembled monolayer (SAM), a second metal layer and a hard mask on the structure formed on the silicon substrate; c) etching partially the second metal layer, the SAM and the first metal layer using the hard mask as an etching mask; d) removing the mask formed in step b) and e) etching partially the SAM to form the nanogap.

It is desirable that the first and second metal layers are formed using aurum (Au).

A method of forming a vertical nanogap for the bio-sensor according to another embodiment of the present invention comprises steps of a) forming sequentially an insulating layer and a first metal layer on a silicon substrate; b) forming sequentially a dielectric layer, a second metal layer and a hard mask on the structure formed on the silicon substrate; c) etching partially the second metal layer, the dielectric layer and the first metal layer using the hard mask as an etching mask; and d) etching partially the dielectric layer formed in step b) to form the nanogap.

It is desirable to use aurum (Au) for forming the first and second metal layers.

It is desirable to use aluminum oxide (Al₂O₃) for forming the dielectric layer in step (a).

A method of manufacturing a nano field effect transistor for a molecular device using the vertical nanogap, comprising steps of a) forming sequentially an insulating layer, a first silicon nitride (Si₃N₄) layer and a first metal layer on a silicon substrate; b) forming sequentially a first dielectric layer, a second metal layer, a second silicon nitride layer and a hard mask on the structure formed on the silicon substrate; c) etching partially the second silicon nitride layer, the second metal layer, the first dielectric layer, the first metal layer and the first silicon nitride layer using the hard mask as an etching mask; d) forming a second dielectric layer, which can be formed and etched anisotropically, on the entire structure; e) etching the second dielectric layer through an etch-back process to form gate oxide layers; f) depositing a gate material on the entire structure; g) etching the gate material deposited in step (f) using a photoresist pattern as the mask to form a gate; h) etching the first dielectric layer formed in step (b) to form the vertical nanogap; and i) forming a molecular layer in the vertical nanogap formed in step (h), the molecular layer having a length which is same as the width of the nanogap.

It is desirable to use aurum (Au) for forming the first and second metal layers.

It is desirable that the dielectric layer formed in step (a) is formed from Al₂O₃.

It is desirable that the dielectric layer formed in step (c) is formed from silicon dioxide (SiO₂).

Other feature and objects of the present invention will become more apparent from the description that follows a preferred embodiment, having reference to the appended drawings and given as examples only as to how the invention may be put into practice.

### BRIEF DESCRIPTION OF THE DRAWINGS

The invention will be described in detail with reference to the following drawings in which numerals refer to elements.

FIG. 1A to FIG. 1F are sectional views showing sequentially a method of forming a planar nanogap for a bio-sensor according to one embodiment of the present invention;

FIG. 2A to FIG. 2E are sectional views showing sequentially a method of forming a vertical nanogap for a bio-sensor according to one embodiment of the present invention;

FIG. 3A to FIG. 3E are sectional views showing sequentially a method of forming a vertical nanogap for a bio-sensor according to another embodiment of the present invention; and

FIG. 4A to FIG. 4F are sectional views showing sequentially a method of manufacturing a molecular device by using the vertical nanogap according to another embodiment of the present invention and molecules as a channel.

### DETAILED DESCRIPTION OF PREFERRED EMBODIMENTS

Hereinafter, a method of forming a nanogap for a molecular device or a bio-sensor and a method of manufacturing a nano field effect transistor for a molecular device or a bio-sensor according to the preferred embodiment of the present invention will be described in detail with reference to the accompanying drawings.

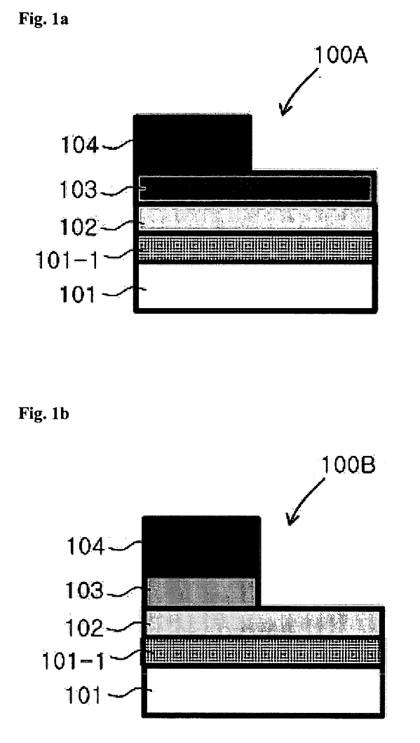

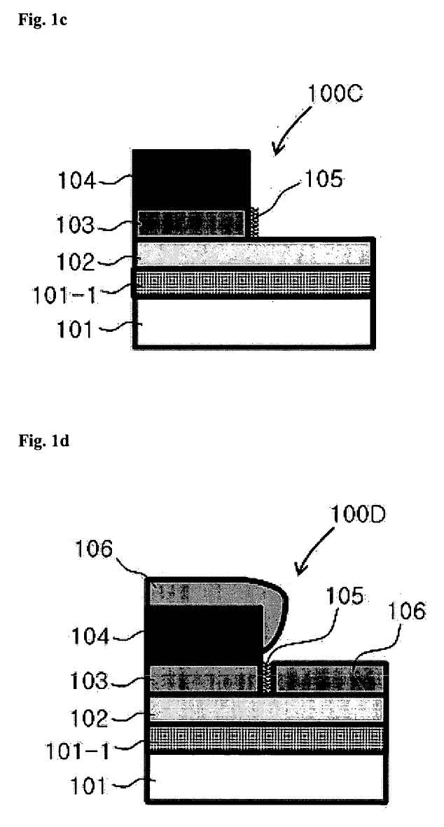

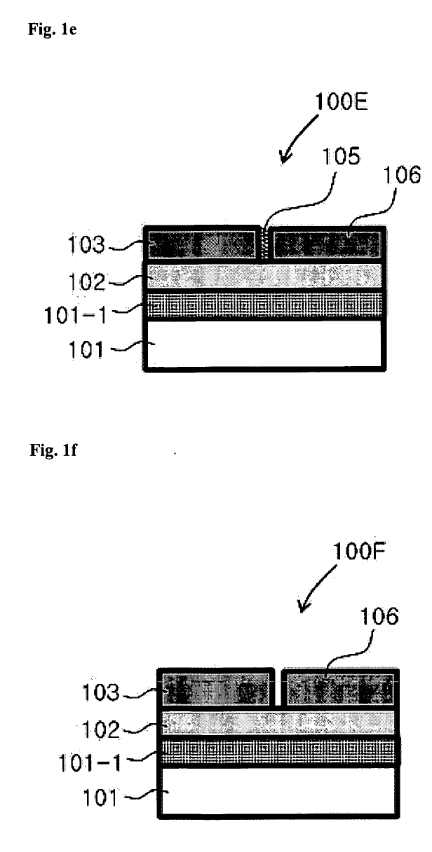

FIG. 1A to FIG. 1F are sectional views showing sequentially a method of forming a planar nanogap for a bio-sensor according to one embodiment of the present invention.

As shown in the drawings, a first aurum (Au) layer (metal layer) is formed on a silicon substrate, and a second Au layer spaced apart from the first Au layer is formed by using a self-assembled monolayer (hereinafter, referred to as “SAM”), so a planar nanogap corresponding to a length of the SAM is formed.

A process for forming the nanogap is described in detail as follows.

First, a back-gate thin layer 101-1 to be formed by a doping process, an insulating layer 102, a first Au layer 103 and a hard mask 104 are sequentially formed on a silicon substrate 101. (FIG. 1A)

The hard mask 104 is made of a material which is not etched during the anisotropical etching process on the first Au layer.

Then, by means of the hard mask 104 on which patterns are formed, the first Au layer 103 is anisotropically etched to form a pattern to be used as one electrode for the planar nanogap by a subsequent process, utilizing the hard mask 104 with a predetermined pattern as an etching mask. (FIG. 1B)

A SAM 105 is then formed on one side (surface) of the first Au layer 103 to form a gap between the first Au layer 103 and a second Au layer to be formed through the subsequent process. (FIG. 1C)

It is desirable to select and use the SAM having an excellent adhesive property to Au.

To form the other electrode for the planar nanogap, the second Au layer 106 is formed on the insulating layer 102 exposed by etching. (FIG. 1D)

Due to the hard mask 104, the second Au layer 106 is not formed on the SAM 105 formed on a side of the first Au layer 103.

The fabrication in which the SAM 105 is then placed between two electrodes (the first and second Au layers), is obtained by removing the hard mask 104.

The second Au layer 106 formed on the hard mask 104 is etched at the same time of removing the hard mask. (FIG. 1E)

The SAM 105 formed between the fist Au layer 103 and the second layer 106 is removed. (FIG. 1F)

To use the planar nanogap as the nano field effect transistor, the SAM 105 should not be removed, and so the above step for removing the first Au layer 103 and the SAM 105 is not required.

The above process allows the manufacture of the planar nanogap or the nano field effect transistor for the bio-sensor according to one embodiment of the present invention and to adjust a width of the nanogap according to a length of the SAM.

It is possible to embody a variable width of the nanogap with a precision degree of a size of an atom according to a size of biological material to be detected by adjusting the chain length of the SAM by the atom unit.

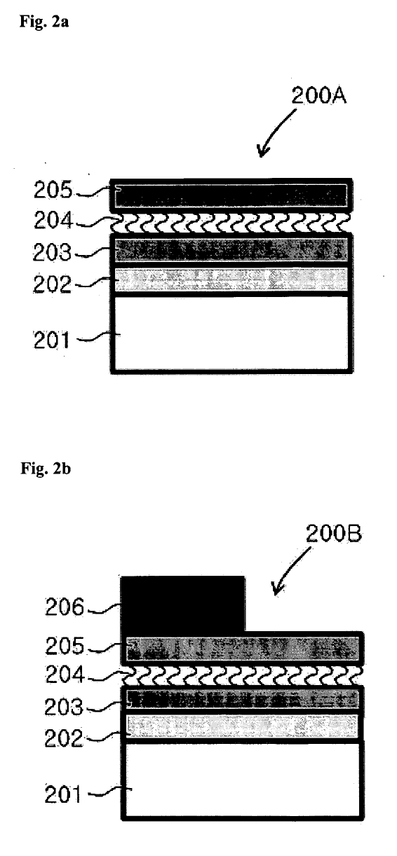

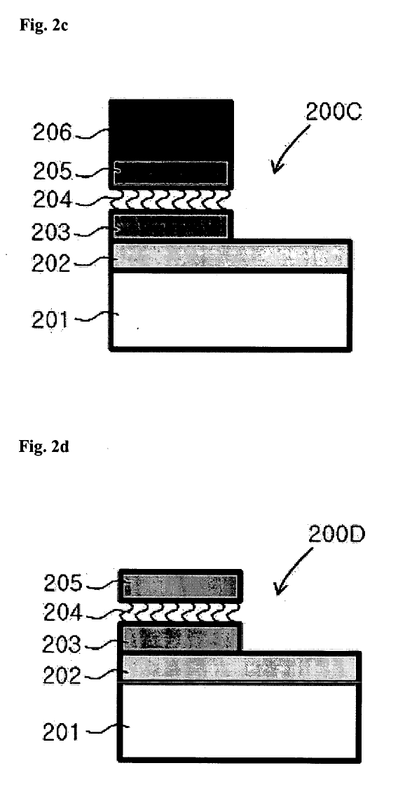

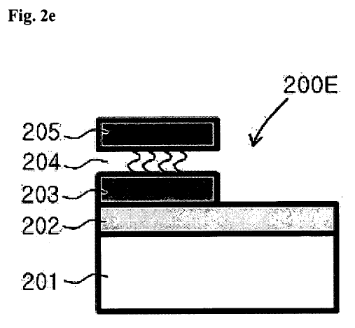

FIG. 2A to FIG. 2E are sectional views showing sequentially a method of forming the vertical nanogap for a bio-sensor according to one embodiment of the present invention.

As shown in the drawings, a first Au layer is formed on a silicon substrate, and a second Au layer spaced apart from the first Au layer is formed by a self-assembled monolayer (hereinafter, referred to as “SAM”), so a vertical nanogap corresponding to a length of the SAM is formed.

An insulating layer 202, a first Au layer 203, a SAM 204 and a second Au layer 205 are sequentially formed on the silicon substrate 201. (FIG. 2A)

A hard mask 206 is then formed on the second Au layer 205. (FIG. 2B)

Since the hard mask 206 is used for selectively etching the first Au layer 203, the SAM 204 and the second Au layer 205 during the subsequent etching processes, it is preferable that the hard mask 206 is made of a material which is not substantially etched under etching condition of an anisotropical etching process for etching away the first Au layer 203, the SAM 204 and the second Au layer 205, with a sufficient thickness not to be etched away during the etching process.

The first Au layer 203, the SAM 204 and the second Au layer 205 are then anisotropically etched by using the hard mask 206 to form a pattern. (FIG. 2C)

The hard mask 206 is then removed, so the fabrication in which the SAM 204 is formed between two electrodes is obtained. (FIG. 2D)

The SAM 204 formed between the first Au layer 203 and the second Au layer 205 is then partially etched to form the nanogap portion. (FIG. 2E)

By the above process, it is possible to manufacture the vertical nanogap for the bio-sensor according to one embodiment of the present invention and to adjust a width of the nanogap according to a length of the SAM.

It is possible to produce a variable width of the nanogap with a precision degree of the size of an atom according to the size of biological material to be detected by adjusting the chain length of the SAM by an atom unit.

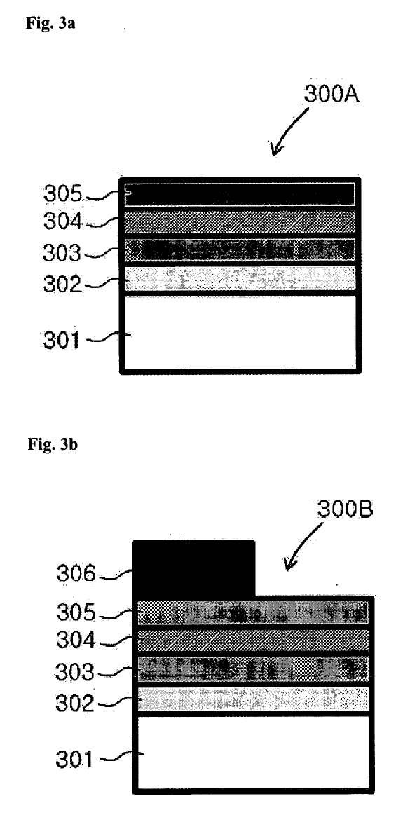

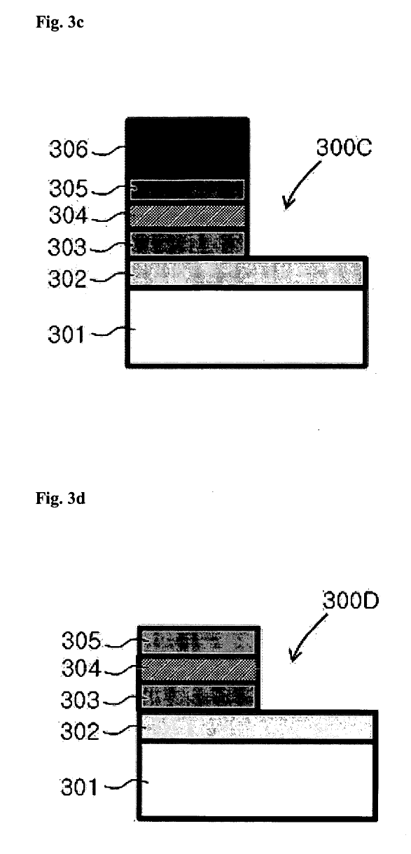

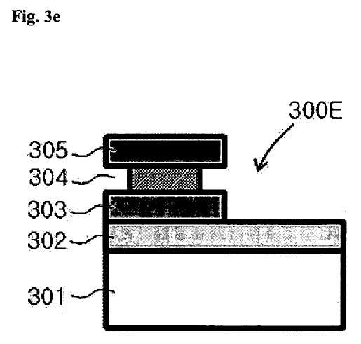

FIG. 3A to FIG. 3E are sectional views showing sequentially a method of forming a vertical nanogap for a bio-sensor according to another embodiment of the present invention.

As shown in the drawings, a first Au layer is formed on a silicon substrate, and a second Au layer spaced apart from the first Au layer is formed by using an aluminum oxide (Al₂O₃) layer, so a vertical nanogap corresponding to the thickness of the Al₂O₃ layer is formed.

An insulating layer 302, a first Au layer 303, an aluminum oxide layer 304 and a second Au layer 305 are sequentially formed on a silicon substrate 301. (FIG. 3A)

The Al₂O₃ layer 304 is formed by the atomic layer deposition (ALD) method.

A layer with the thickness equivalent to the size of one atom may be formed by using an ALD process.

A hard mask 306 is then formed on the second Au layer 305. (FIG. 3B)

Since the hard mask 306 is used to selectively etch the first Au layer 303, the Al₂O₃ layer 304 and the second Au layer 305 during the subsequent etching processes, it is preferable that the hard mask 306 is made of a material which is not etched under etching conditions of an anisotropical etching process for etching the first Au layer 303, the Al₂O₃ layer 304 and the second Au layer 305, with sufficient thickness not to be etched away during the etching process.

The first Au layer 303, the Al₂O₃ layer 304 and the second Au layer 305 are then anisotropically etched by using the hard mask 206 to form a pattern to be formed as a vertical nanogap in the subsequent process. (FIG. 3C)

The hard mask 306 is then removed, so the fabrication in which the Al₂O₃ layer 304 is formed between two electrodes is formed. (FIG. 3D)

The Al₂O₃ layer 304 then formed between the first Au layer 303 and the second Au layer 305 is partially etched to form the nanogap portion. (FIG. 3E)

By the above process, it is possible to manufacture the vertical nanogap for the bio-sensor according to another embodiment of the present invention and to adjust a width of the nanogap to a precision degree of a size of sub-nanometer according to a thickness of the Al₂O₃ layer formed by the atomic layer deposition method.

Artificial adjustment of the thickness of the layer is possible forf the various conditions (for example, a gas pressure and a processing time, etc) of the atomic layer deposition process, so that the thin layers having the various thicknesses can be obtained.

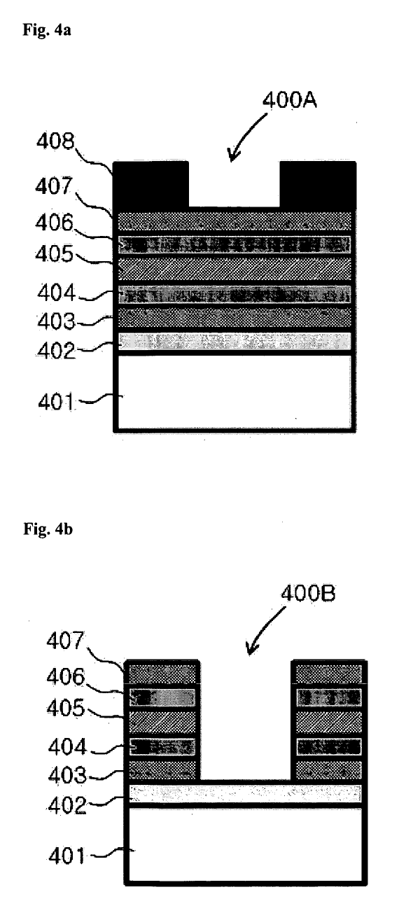

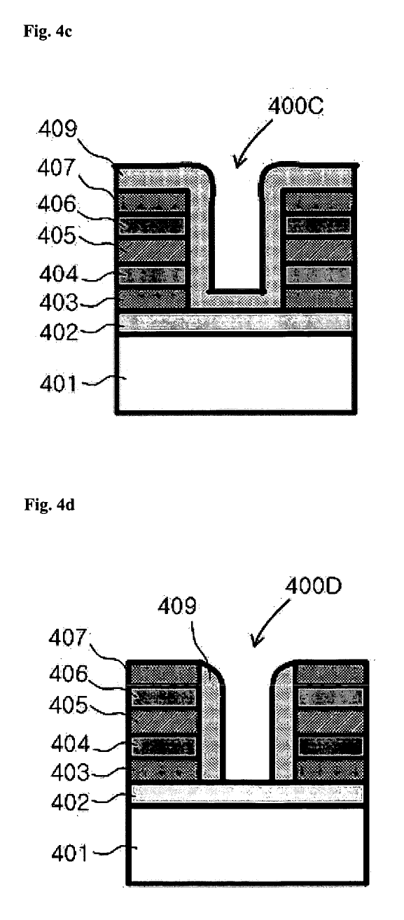

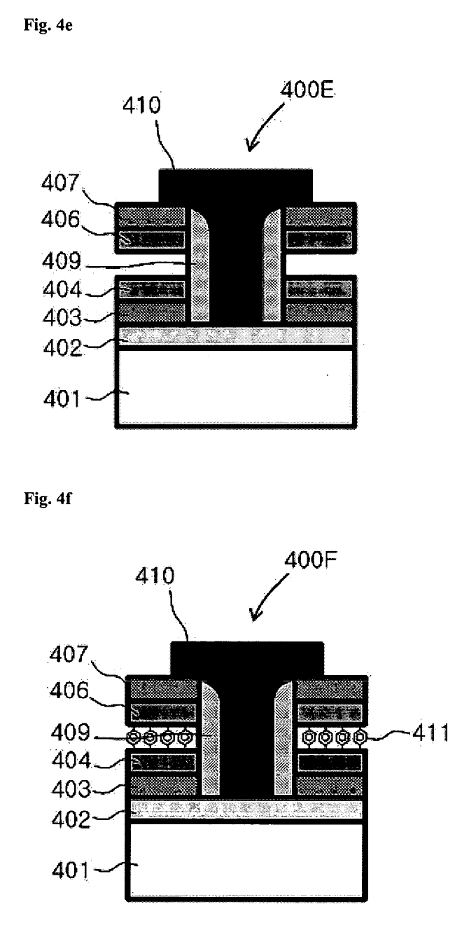

FIG. 4A to FIG. 4F are sectional views showing sequentially a method of manufacturing a molecular device using the vertical nanogap for the molecular device according to another embodiment of the present invention and the molecules as a gate dielectric layer.

As shown in the drawings, a first Au layer is formed on a silicon substrate, and a second Au layer spaced apart from the first Au layer is formed by using an aluminum oxide (Al₂O₃) layer, so a vertical nanogap corresponding to a thickness of the Al₂O₃ layer is formed.

The nano field effect transistor is then produced by forming the molecules with a length which is same as the size of the gap and acting as a gate dielectric layer in the formed vertical nanogap.

The insulating layer 402, a first silicon nitride (Si₃N₄) layer 403, a first Au layer 404, an aluminum oxide (Al₂O₃) layer 405, a second Au layer 406, a second silicon nitride (Si₃N₄) layer 407 and a hard mask 408 are sequentially formed on the silicon substrate 401. (FIG. 4A)

The Al₂O₃ layer 405 is formed by the atomic layer deposition (ALD) method.

A layer of the thickness equivalent to the size of one atom may be formed by using the ALD process.

Since the hard mask 408 is used to etch the first Si₃N₄ layer 403, the first Au layer 404, the Al₂O₃ layer 405, the second Au layer 406 and the second Si₃N₄ layer 407, the hard mask 408 is made from the material which is not etched during the anisotropical etching process for the first Si₃N₄ layer 403, the first Au layer 404, the Al₂O₃ layer 405, the second Au layer 406 and the second Si₃N₄ layer 407, with a sufficient thickness not to be etched away during the etching process.

The first Si₃N₄ layer 403, the first Au layer 404, the Al₂O₃ layer 405, the second Au layer 406 and the second Si₃N₄ layer 407 are then anisotropically etched by using the hard mask 408 as the mask, and the hard mask 408 is then removed. (FIG. 4B)

A silicon dioxide is then deposited on the entire structure to form the SiO₂ layer 409. (FIG. 4C)

The SiO₂ layers 409 are used for forming SiO₂ side-walls between the Au layer and a gate to be formed in the subsequent process.

The SiO₂ layer 409 is etched back to form two side-walls at a portions at which a gate is scheduled to form. (FIG. 4D).

A gate material 410 is deposited on the entire structure, and the deposited gate material is then patterned through the photoresist pattern to form the gate 410. The Al₂O₃ layer 405 is then etched to form the nanogap in which a molecular layer is scheduled to form. (FIG. 4E)

A molecular layer 411 is then formed in the same width as that of the nanogap formed by etching the Al₂O₃ layer 405. (FIG. 4F)

By the above process, the vertical nanogap for the bio-sensor can be manufactured according to another embodiment of the present invention and to adjust a width of the nanogap to a precision degree of a size of sub-nanometer according to a thickness of the Al₂O₃ layer formed by the atomic layer deposition method.

The nanoFET can be manufactured by forming the molecular layer in the nanogap formed through the process described previously.

The highly integrated nanogap structure can be manufactured through the simple and reproducible processes of the method of manufacturing the nanogap or the nano field effect transistor for the molecular device or the bio-sensor according to the present invention.

The nanogap of several nano meters, which can not be embodied by the conventional process, can be formed with a selection of the appropriate SAM and through the atomic layer deposition method.

In addition, it is possible to form the nanogap having a size which is suitable for the biological material to be detected with a precision degree of a sub-nanometer through various kinds of the SAM and the atomic layer deposition process.

The present invention is the most practical technology utilizing the current semiconductor process for manufacturing a semiconductor device and a technology for forming the nanogap which can substitute for the conventional lithography method having a limit of scaling.

It is intended that the embodiments of the present invention described above and illustrated in the drawings should not be construed as limiting the technical spirit of the present invention. The scope of the present invention is defined only by the appended claims. Those skilled in the art can make various changes and modifications thereto without departing from its true spirit. Therefore, various changes and modifications obvious to those skilled in the art will fall within the scope of the present invention.

What is claimed is:

1. A method of forming a planar nanogap for a bio-sensor, comprising the steps of;
(a) forming sequentially an insulating layer, a first metal layer and a hard mask on a silicon substrate;
(b) etching partially the first metal layer using a mask pattern as a mask;
(c) forming a self-assembled monolayer (SAM) on a side of the first metal layer to form a nanogap on the silicon substrate;
(d) depositing metal on the silicon substrate to form a second metal layer;
(e) by etching the mask formed in step (a), removing the metal deposited on the hard mask by using a lift-off process; and
(f) etching the SAM formed in step (c) to form the nanogap.

2. The method of forming the planar nanogap for the bio-sensor as claimed in claim 1, wherein the first and second metal layers are formed of aurum (Au).

3. The method of forming the planar nanogap for the bio-sensor as claimed in claim 1, wherein the first metal layer in step (a) and the second metal layer in step (d) are formed through any one of a vapor deposition method, a sputtering method or a pulsed laser deposition method.

4. A bio-sensor manufactured by the method of forming the planar nanogap for the bio-sensor according to any one of claim 1 to claim 3.

5. A method of forming a vertical nanogap for the bio-sensor, comprising steps of;
a) forming sequentially an insulating layer and a first metal layer on a silicon substrate;
b) forming sequentially a self-assembled monolayer (SAM), a second metal layer and a hard mask on the structure formed on the silicon substrate;
c) etching partially the second metal layer, the SAM and the first metal layer by using the hard mask as an etching mask;
d) removing the hard mask formed in step b); and
e) etching partially the SAM to form the nanogap.

6. The method of forming the vertical nanogap for the bio-sensor as claimed in claim 5, wherein the first and second metal layers are formed of aurum (Au).

7. A bio-sensor manufactured by the method of forming the vertical nanogap for the bio-sensor according to claim 5 or claim 6.

8. A method of forming a vertical nanogap for the bio-sensor, comprising the steps of;
a) forming sequentially an insulating layer and a first metal layer on a silicon substrate;
b) forming sequentially a dielectric layer, a second metal layer and a hard mask on the structure formed on the silicon substrate;
c) etching partially the second metal layer, the dielectric layer and the first metal layer by using the hard mask as a mask; and
d) etching partially the dielectric layer formed in step b) to form the nanogap.

9. The method of forming the vertical nanogap for the bio-sensor as claimed in claim 8, wherein the first and second metal layers are formed of aurum (Au).

10. The method of forming the vertical nanogap for the bio-sensor as claimed in claim 8, wherein the dielectric layer formed in step (a) is formed of aluminum oxide (Al₂O₃).

11. A bio-sensor manufactured by the method of forming the vertical nanogap for the bio-sensor according to any one of claim 8 to claim 10.

12. A method of manufacturing a nano field effect transistor for a molecular device using the vertical nanogap, comprising (the) steps of;
a) forming sequentially an insulating layer, a first silicon nitride (Si₃N₄) layer and a first metal layer on a silicon substrate;
b) forming sequentially a first dielectric layer, a second metal layer, a second silicon nitride layer and a hard mask on the structure formed on the silicon substrate;
c) etching partially the second silicon nitride layer, the second metal layer, the first dielectric layer, the first metal layer and the first silicon nitride layer by using the hard mask as a mask;
d) forming a second dielectric layer, which can be formed as a film and etched anisotropically, on the entire structure;
e) etching the second dielectric layer through an etch-back process to form an oxide layer for the gate;
f) depositing a gate material on the entire structure;
g) etching the gate material deposited in step (f) by using a photoresist pattern as the mask to form the gate;
h) etching the first dielectric layer formed in step (b) to form the vertical nanogap; and
i) forming a molecular layer in the vertical nanogap formed in step (h), the molecular layer having a length which is same as the width of the nanogap.

13. The method of manufacturing the nano field effect transistor for the molecular device using the vertical nanogap as claimed in claim 12, wherein the first and second metal layers are formed of aurum (Au).

14. The method of manufacturing the nano field effect transistor for the molecular device using the vertical nanogap as claimed in claim 12, wherein the first dielectric layer formed in step (a) is formed of aluminum oxide (Al₂O₃).

15. The method of manufacturing a nano field effect transistor for a molecular device using the vertical nanogap as claimed in claim 12, wherein the second dielectric layer formed in step (c) is formed of silicon dioxide (SiO₂).

16. A nano field effect transistor manufactured by the method of manufacturing the nano field effect transistor for the molecular device using the vertical nanogap according to any one of claim 12 to claim 15.
